(19) United States
(12) Patent Application Publication
(10) Pub. No.: US 2007/0279974 A1
(43) Pub. Date: Dec. 6, 2007

(54) Forming heaters for phase change memories with select devices

(76) Inventors: Charles H. Dennison, San Jose, CA (US); John M. Peters, San Jose, CA (US)

Correspondence Address: TROP PRUNER & HU, PC, 1616 S. VOSS ROAD, SUITE 750, HOUSTON, TX, 77057-2631, US

(21) Appl. No.: 11/447,819

(22) Filed: Jun. 6, 2006

(51) Int. Cl. G11C 11/00; H01L 23/58

(52) U.S. Cl. 365/163; 257/629

(57) ABSTRACT

Rather than depositing a heater material into a pore, a heater material may be first blanket deposited over a select device. The heater material may then be covered by a mask, such that the mask and the heater material may be etched to form a stack. Then, the region between adjacent stacks that form separate cells may be filled with an insulator. After removing the mask material, a pore is then formed in the insulator over the heater. This may then be filled with chalcogenide to form a phase change memory.

### BACKGROUND

This invention relates generally to phase change memories.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is an enlarged, cross-sectional view at an early stage of manufacture in the row direction in accordance with one embodiment;

FIG. 2 is an enlarged, cross-sectional view corresponding to FIG. 1 in the column direction in accordance with one embodiment;

FIG. 3 is an enlarged, cross-sectional view in accordance with another embodiment;

FIG. 4 is an enlarged, cross-sectional view in accordance with the embodiment of FIG. 3;

FIG. 5 is an enlarged, cross-sectional view at a stage subsequent to that shown in FIG. 2 in accordance with one embodiment;

FIG. 6 is an enlarged, cross-sectional view at a stage subsequent to that shown in FIG. 3 in accordance with one embodiment;

FIG. 7 is an enlarged, cross-sectional view at a stage subsequent to that shown in FIG. 5 in accordance with one embodiment;

FIG. 8 is an enlarged, cross-sectional view at a stage subsequent to that shown in FIG. 6 in accordance with one embodiment;

FIG. 9 is an enlarged, cross-sectional view at a stage subsequent to that shown in FIG. 7 in accordance with one embodiment;

FIG. 10 is an enlarged, cross-sectional view at a stage subsequent to that shown in FIG. 8 in accordance with one embodiment;

FIG. 11 is an enlarged, cross-sectional view at a stage subsequent to that shown in FIG. 9 in accordance with one embodiment;

FIG. 12 is an enlarged, cross-sectional view at a stage subsequent to that shown in FIG. 10 in accordance with one embodiment;

FIG. 13 is an enlarged, cross-sectional view at a stage subsequent to that shown in FIG. 11 in accordance with one embodiment;

FIG. 14 is an enlarged, cross-sectional view at a stage subsequent to that shown in FIG. 12 in accordance with one embodiment;

FIG. 15 is an enlarged, cross-sectional view at a stage subsequent to that shown in FIG. 13 in accordance with one embodiment;

FIG. 16 is an enlarged, cross-sectional view at a stage subsequent to that shown in FIG. 14 in accordance with one embodiment;

FIG. 17 is an enlarged, cross-sectional view at a stage subsequent to that shown in FIG. 15 in accordance with one embodiment;

FIG. 18 is an enlarged, cross-sectional view at a stage subsequent to that shown in FIG. 16 in accordance with one embodiment;

FIG. 19 is an enlarged, cross-sectional view at a stage subsequent to that shown in FIG. 17 in accordance with one embodiment;

FIG. 20 is an enlarged, cross-sectional view at a stage subsequent to that shown in FIG. 18 in accordance with one embodiment;

FIG. 21 is an enlarged, cross-sectional view at a stage corresponding to the stage of manufacture shown in FIG. 19 in accordance with another embodiment;

FIG. 22 is an enlarged, transverse cross-sectional view of the embodiment shown in FIG. 21; and

FIG. 23 is a system depiction of one embodiment of the present invention.

### DETAILED DESCRIPTION

In accordance with some embodiments of the present invention, a heater for a phase change memory having a select device, such as an ovonic threshold switch, may be formed without using pore deposition processes. A pore deposition process is a process wherein the heater material is deposited into a pore. Such a deposition process has many problems. One problem is the creation of keyholing or voids within the deposited heater material. Another problem is that the height of the heater is set by a dry or wet etch back and, thus, may be hard to control.

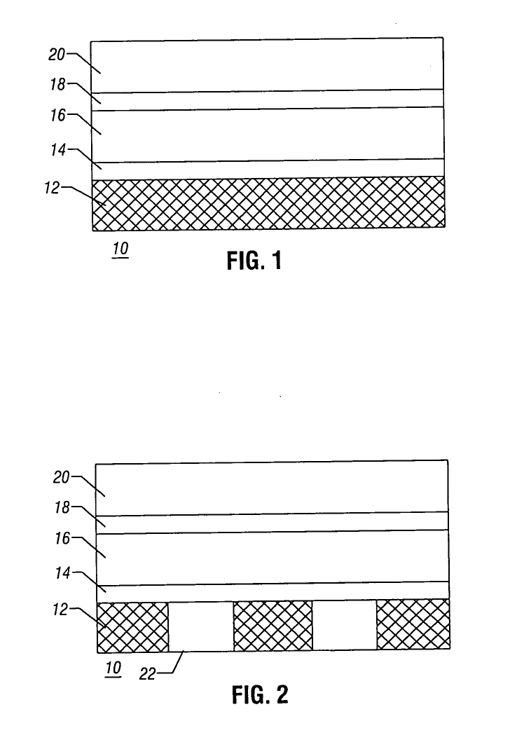

Referring to FIG. 1, at an early stage, a row metal 12 may be formed over a substrate 10. The substrate 10 may, for example, be an interlayer dielectric or even a semiconductor substrate. While the layer 12 is referred to as a row metal, this is simply a convention and it equally well could be considered a column in some embodiments.

In some embodiments, over the row metal 12 may be formed a select device, such as an ovonic threshold switch, including an upper electrode 18, an ovonic threshold switch material 16, and a bottom electrode 14 resting on the row metal 12 in one embodiment of the present invention. Other select or access devices may also be used, including MOS or bipolar transistors or diodes.

Thereafter, a heater 20 may be formed. The heater 20 may be blanket deposited on a planar surface. For example, the heater 20 may be titanium silicon nitride in one embodiment. The same structure is shown in FIG. 2, but taken in the direction of what ultimately will be the column that extends transversely to the row metal 12. Thus, the row metal 12 is elongate and adjacent row metals 12 are separated by insulating layers 22.

One result of placing the select device on the row metal is that the heater 20 is now separated from the row metal 12. Where the row metal 12 is formed of copper, this may have the advantage of making the process more resilient or impervious to copper extrusion defects. Copper in-diffusion may adversely affect the heater, for example, by reducing its resistivity. Moreover, the full surface of the heater 20 is presented for anneal and/or densification steps. This may be advantageous for stability during device cycling.

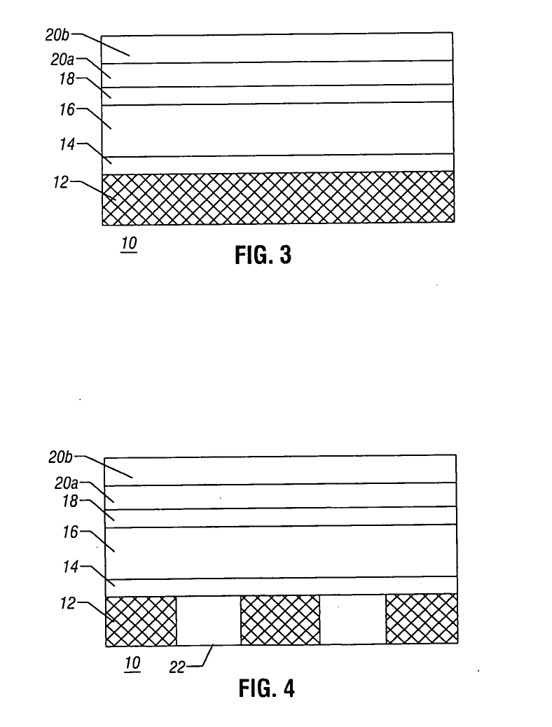

Referring to FIGS. 3 and 4, in accordance with another embodiment of the present invention, the heater material may be formed in distinct layers 20a and 20b. The layer 20a may be a low to medium resistance heater material and the layer 20b may be a higher resistance heater material. In one embodiment, the material 20a may have a variable resistance which increases from bottom to top, ultimately matching the higher resistance of the material 20b. Thermal insulation may be enhanced, in some embodiments, by layering the heater, creating boundary layers that increase thermal insulation in the vertical direction. The corresponding structure is shown in FIG. 4 in the y direction.

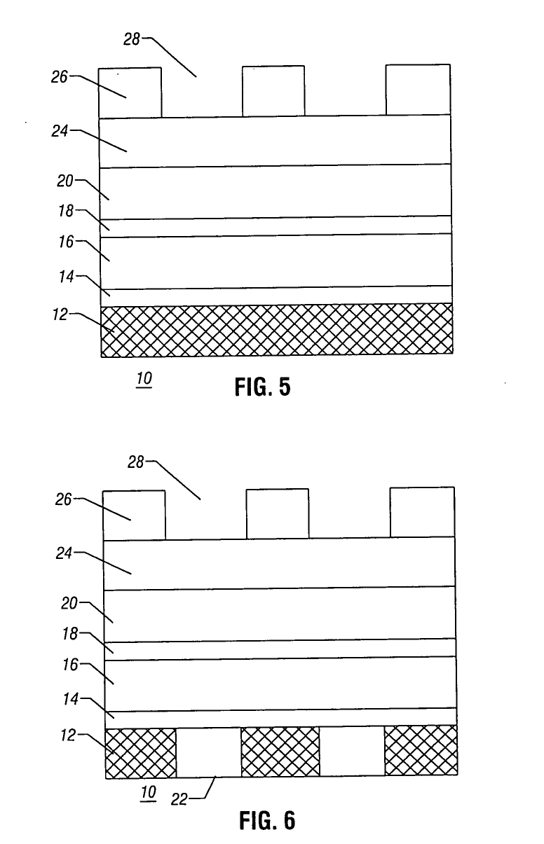

Referring to FIG. 5, which, again, is in the row direction as was the case in FIG. 1, a hard mask 24 is formed over the heater 20. The hard mask 24, in one embodiment, may be silicon nitride. In general, it is desirable that the hard mask 24 be formed of a material which is selectively etchable relative to the surrounding materials including the underlying heater 20, for reasons which will be more apparent subsequently. Over the hard mask 24 may be formed patterned photoresist 26. The same structure appears in FIG. 6, taken in the column direction.

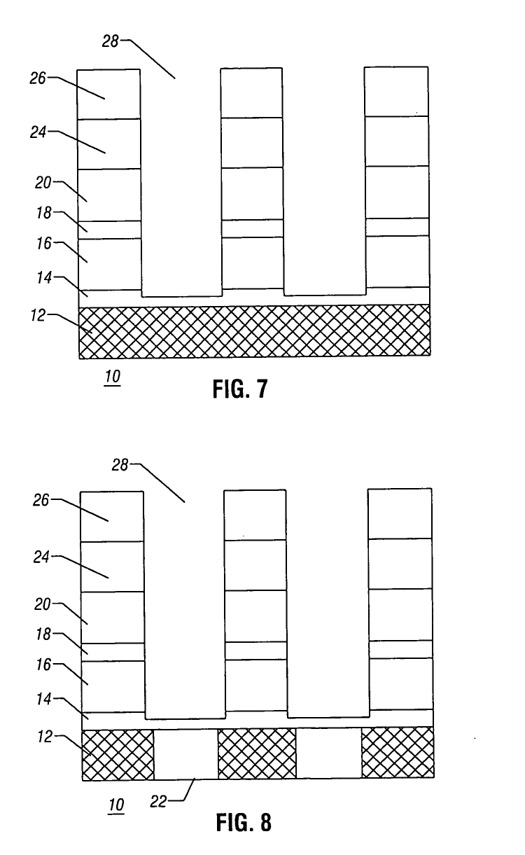

Referring to FIG. 7, the patterned photoresist 26 is then used as an etch mask to etch the hard mask 24 and the heater 20 through the openings 28 in the photoresist 26 in one embodiment. The structure including the heater 20 is only partially etched down to the bottom electrode 14 so that the photoresist 26 can be removed before the row metal 12 is exposed. Otherwise, copper corrosion could occur during the resist ash. The corresponding structure in the column direction is shown in FIG. 8.

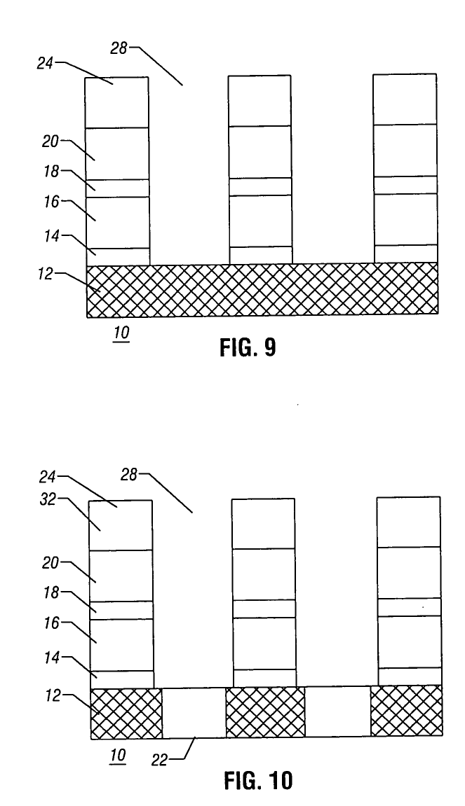

Then, referring to FIG. 9, after removing the photoresist 26 using a resist ash, the etching of the heater 20 can be completed down to the row metal 12. The corresponding structure in the column direction is shown in FIG. 10.

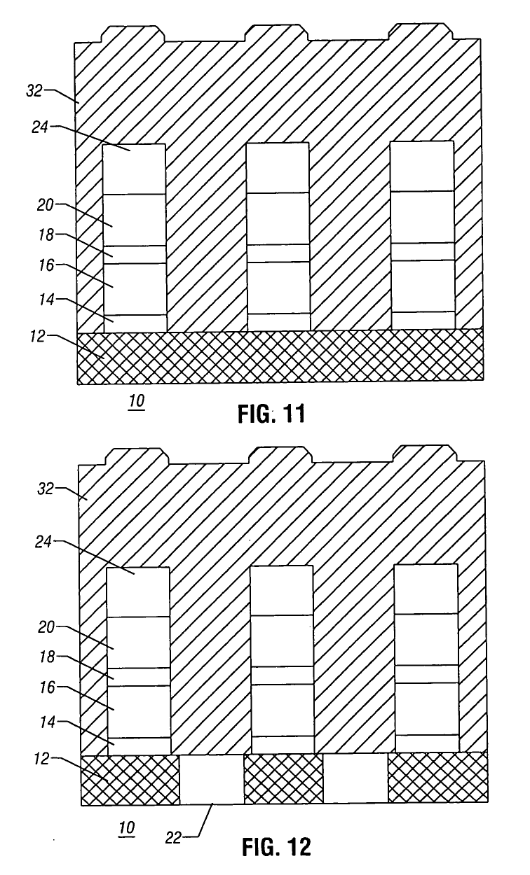

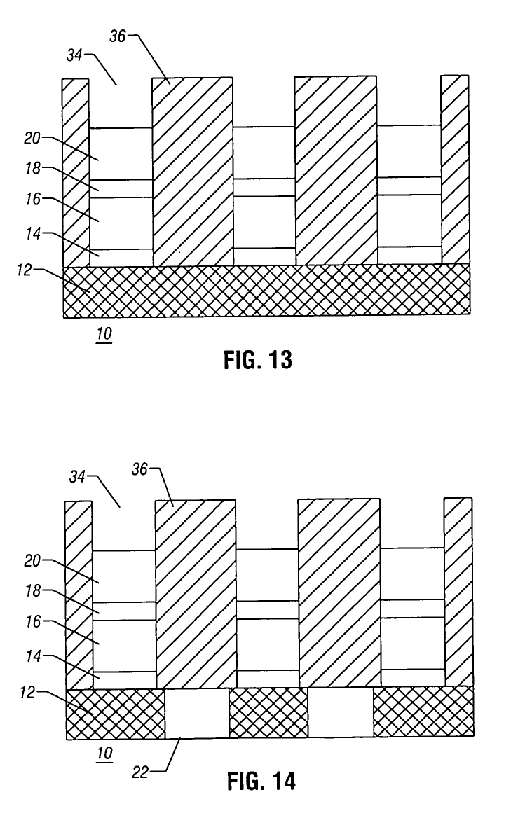

Referring next to FIGS. 11 and 12, an insulator 32 may be blanket deposited over the entire structure. In some embodiments, the insulator 32 may be high density plasma (HDP) oxide fill. As another alternative, plasma enhanced chemical vapor deposition nitride may be used with HDP oxide. As shown in FIGS. 13 and 14, the structure of FIGS. 11 and 12 may be planarized down to the hard mask 24.

Then, it is desirable to remove the remaining portions of the hard mask 24. This may be done using a wet etch, such as a hot phosphoric acid etch at 70° C., that attacks the hard mask 24 at a much faster rate than the insulator 32 or the heater 20. In other words, the etch is selective to the hard mask 24 versus the surrounding materials, namely, the insulator 32 and the heater 20. Where the insulator 32 is HDP oxide and the heater 20 is titanium silicon nitride, hot phosphoric acid at 70° C. may be effective. In other embodiments, a dry etch that selectively etches the hard mask at a faster rate than the insulator 32 or heater 20 may be used.

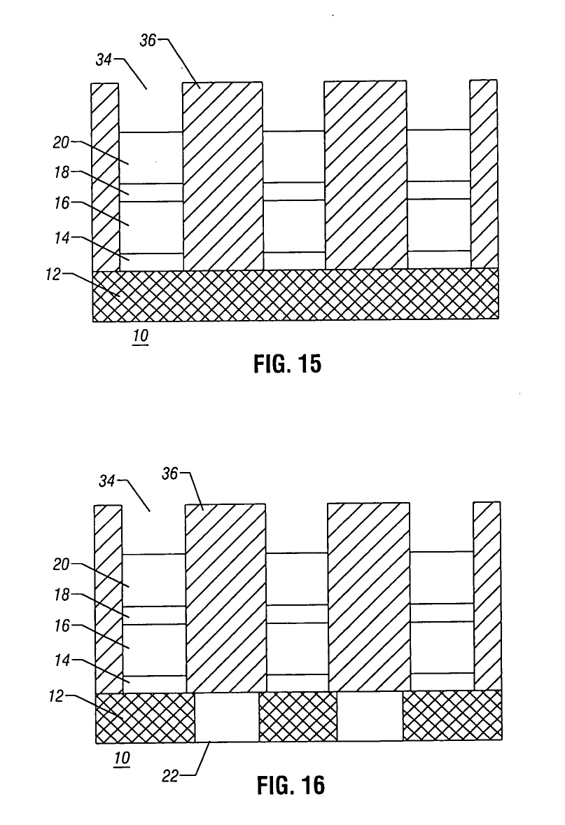

A self-aligned process may be implemented. In other words, because of the selectivity of the etch, the material that is removed corresponds precisely to that of the hard mask 24, leaving a pore 34, as shown in FIGS. 15 and 16, nicely aligned above the heater 20.

The heater 20 may be free of keyholing because it was blanket deposited. Moreover, the height of the heater 20 is set by deposition (rather than by an etch back process) and is, therefore, inherently controllable. The depth of the pore 34 is set both by the thickness of the hard mask 24 and the ability of the planarization step to stop on the end point on the top surface.

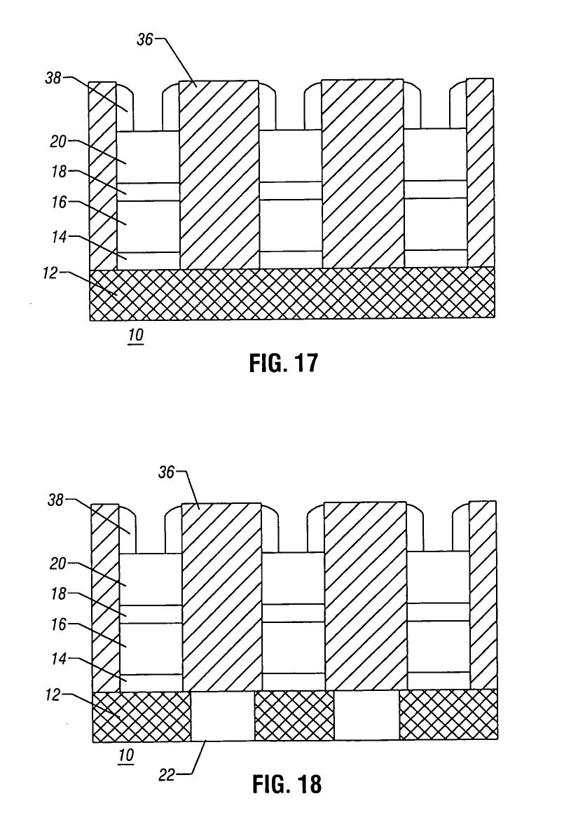

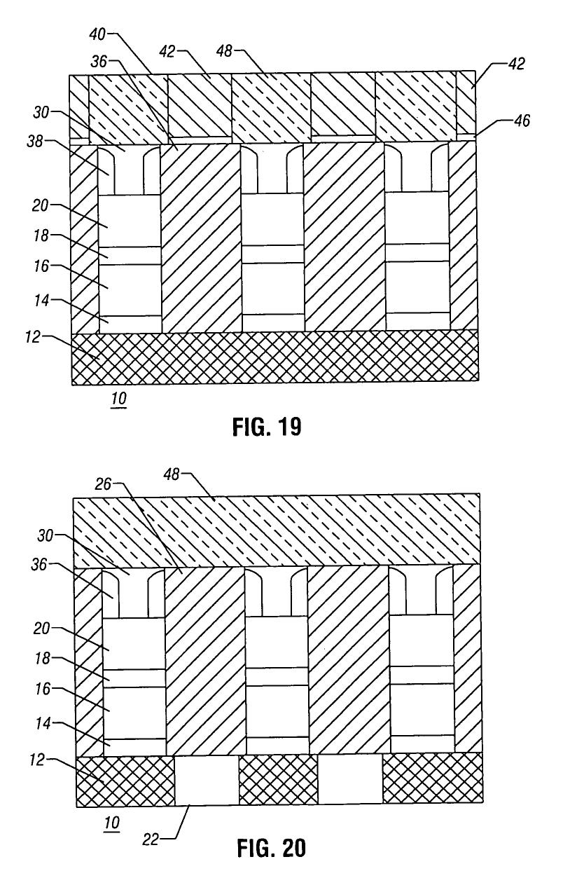

In some embodiments, as shown in FIGS. 17 and 18, a sidewall spacer 38 may be deposited and anisotropically etched to reduce the pore's critical dimension. Then, the remaining pore 34 may be filled with a chalcogenide material 30 which is thereafter planarized to align with the top surface of the insulator 32 as shown in FIGS. 19 and 20. An upper electrode 40 may be deposited, patterned, and etched. The upper electrode 40 extends generally transversely to the row metal 12. It too may be formed of copper in some embodiments. In some embodiments, it may be desirable to provide a copper barrier layer (not shown) which separates the column electrode 40 from the rest of the structure and another copper barrier layer between the material 12 and the overlying structure.

In accordance with some embodiments of the present invention, an insulating layer 46 may be initially deposited. The insulating layer may be formed of silicon nitride. Then an oxide 42 may be deposited. Finally, lithography and etching may be utilized to form the column pattern, followed by deposition of the columns 40. Thereafter, the structure may be subjected to chemical mechanical planarization.

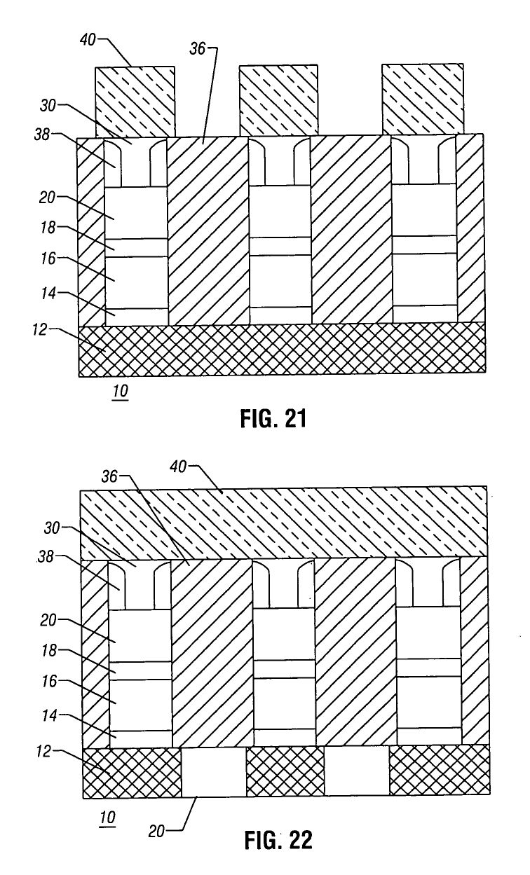

In accordance with another embodiment shown in FIGS. 21 and 22, a non-damascene approach may be utilized compared to damascene approach of FIGS. 19 and 20. A column metal may be deposited with bottom barrier layers. For example, a stack of titanium nitride, titanium, AlCu, and titanium nitride or titanium, followed by titanium nitride, followed by AlCu, followed by titanium nitride may be utilized. Then, lithography and etching may be utilized to form the columns 40.

In accordance with another embodiment of the present invention, the hard mask 24 may be implemented by a thermally decomposable material. Namely, a material which thermally decomposes at a temperature higher than the deposition temperature of the insulator 32 may be used instead of selective etching. Upon the application of heat of a suitable temperature, the material vaporizes or thermally decomposes, creating the gap corresponding to the pore 34 shown in FIG. 15. A variety of polymer materials may have suitable decomposition temperatures including polynorbornene, as one example. Other materials which are used in sacrificial applications may be used as well, including those that may be removed by exposure to various environmental circumstances including radiation exposure, chemical exposure, or heat, to mention a few examples.

In accordance with another embodiment of the present invention, the hard mask 24 may be constructed as a two layer construction. The first layer may be a relatively thin nitride, covered by a thicker material such as an oxide or SiON, as two examples. The thin nitride may act as a stopping layer during the etch shown in FIG. 7. This avoids any exposure of the heater 20 during the resist strip in an oxidizing ambient. Moreover, the nitride lower layer may also reduce the possibility of oxidation of the heater during any oxide hard mask deposition. After stripping the resist, the process would continue as before, etching the residual nitride and then the heater 20. Use of a nitride/oxide stack may assist the etch because usually the heater is very similar to nitride.

Programming of the chalcogenide material 30 to alter the state or phase of the material may be accomplished by applying voltage potentials to the lower electrode 12 and upper electrode 40, thereby generating a voltage potential across the select device and memory element. When the voltage potential is greater than the threshold voltages of select device and memory element, then an electrical current may flow through the chalcogenide material 30 in response to the applied voltage potentials, and may result in heating of the chalcogenide material 30.

This heating may alter the memory state or phase of the chalcogenide material 30. Altering the phase or state of the chalcogenide material 30 may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in an a crystalline or semi-crystalline state. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature to amorphosize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

A select device may operate as a switch that is either “off” or “on” depending on the amount of voltage potential applied across the memory cell, and more particularly whether the current through the select device exceeds its threshold current or voltage, which then triggers the device into the on state. The off state may be a substantially electrically nonconductive state and the on state may be a substantially conductive state, with less resistance than the off state.

In the on state, the voltage across the select device, in one embodiment, is equal to its holding voltage V_{H} plus IxRon, where Ron is the dynamic resistance from the extrapolated X-axis intercept, V_{H}. For example, a select device may have threshold voltages and, if a voltage potential less than the threshold voltage of a select device is applied across the select device, then the select device may remain “off” or in a relatively high resistive state so that little or no electrical current passes through the memory cell and most of the voltage drop from selected row to selected column is across the select device. Alternatively, if a voltage potential greater than the threshold voltage of a select device is applied across the select device, then the select device may “turn on,” i.e., operate in a relatively low resistive state so that electrical current passes through the memory cell. In other words, one or more series connected select devices may be in a substantially electrically nonconductive state if less than a predetermined voltage potential, e.g., the threshold voltage, is applied across select devices. Select devices may be in a substantially conductive state if greater than the predetermined voltage potential is applied across select devices. Select devices may also be referred to as an access device, an isolation device, or a switch.

In one embodiment, each select device may comprise a switch material 16 such as, for example, a chalcogenide alloy, and may be referred to as an ovonic threshold switch, or simply an ovonic switch. The switch material 16 of select devices may be a material in a substantially amorphous state positioned between two electrodes that may be repeatedly and reversibly switched between a higher resistance “off” state (e.g., greater than about ten megaohms) and a relatively lower resistance “on” state (e.g., about one thousand Ohms in series with V_{H}) by application of a predetermined electrical current or voltage potential. In this embodiment, each select device may be a two terminal device that may have a current-voltage (I-V) characteristic similar to a phase change memory element that is in the amorphous state. However, unlike a phase change memory element, the switching material of select devices may not change phase. That is, the switching material of select devices may not be a programmable material, and, as a result, select devices may not be a memory device capable of storing information. For example, the switching material of select devices may remain permanently amorphous and the I-V characteristic may remain the same throughout the operating life.

In the low voltage or low electric field mode, i.e., where the voltage applied across select device is less than a threshold voltage (labeled V_{TH}), a select device may be “off” or nonconducting, and exhibit a relatively high resistance, e.g., greater than about 10 megaohms. The select device may remain in the off state until a sufficient voltage, e.g., V_{TH}, is applied, or a sufficient current is applied, e.g., I_{TH}, that may switch the select device to a conductive, relatively low resistance on state. After a voltage potential of greater than about V_{TH} is applied across the select device, the voltage potential across the select device may drop (“snapback”) to a holding voltage potential, V_{H}. Snapback may refer to the voltage difference between V_{TH} and V_{H} of a select device.

In the on state, the voltage potential across select device may remain close to the holding voltage of V_{H} as current passing through select device is increased. The select device may remain on until the current through the select device drops below a holding current, I_{H}. Below this value, the select device may turn off and return to a relatively high resistance, nonconductive off state until the V_{TH} and I_{TH} are exceeded again.

In some embodiments, only one select device may be used. In other embodiments, more than two select devices may be used. A single select device may have a V_{H} about equal to its threshold voltage, V_{TH}, (a voltage difference less than the threshold voltage of the memory element) to avoid triggering a reset bit when the select device triggers from a threshold voltage to a lower holding voltage called the snapback voltage. An another example, the threshold current of the memory element may be about equal to the threshold current of the access device even though its snapback voltage is greater than the memory element's reset bit threshold voltage.

One or more MOS or bipolar transistors or one or more diodes (either MOS or bipolar) may be used as the select device. If a diode is used, the bit may be selected by lowering the row line from a higher deselect level. As a further non-limiting example, if an n-channel MOS transistor is used as a select device with its source, for example, at ground, the row line may be raised to select the memory element connected between the drain of the MOS transistor and the column line. When a single MOS or single bipolar transistor is used as the select device, a control voltage level may be used on a “row line” to turn the select device on and off to access the memory element.

In some embodiments, one masking process may be used to form both the memory element and the select device. This can save one masking and alignment operation, in some embodiments, relative to a process with the select device over the memory element.

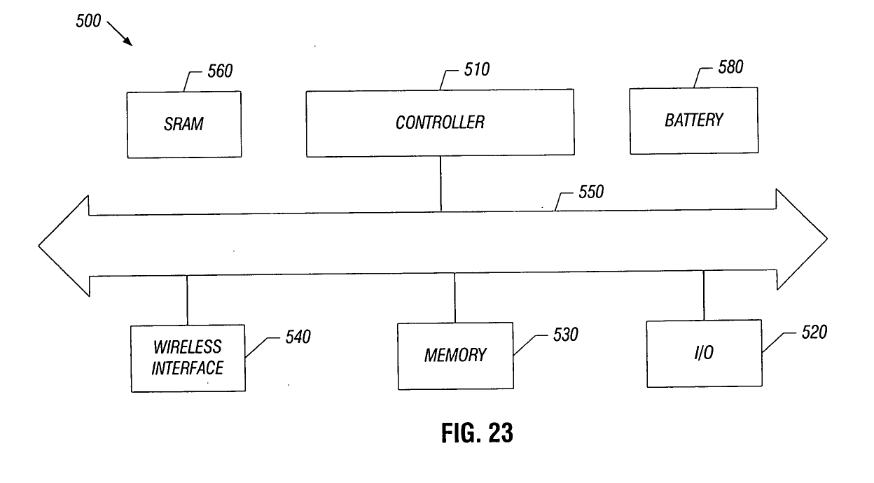

Turning to FIG. 23, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a planar heater layer over a select device of a phase change memory.

2. The method of claim 1 including forming the select device in the form of an ovonic threshold switch.

3. The method of claim 2 including forming the ovonic threshold switch over a metal layer.

4. The method of claim 3 including forming a phase change memory element over said select device.

5. The method of claim 1 including depositing multiple distinct layers of heater material to form said planar heater layer.

6. The method of claim 1 including forming a mask and etching vertically through said planar heater to form distinct phase change memory cells having select devices.

7. The method of claim 1 including forming a phase change memory element over the select device.

8. The method of claim 1 including forming a planar upper surface of said select device and blanket depositing said heater layer on said planar surface.

9. A phase change memory comprising:
a heater formed over said selective dice, said heater comprising a planar layer; and
a phase change memory formed over said heater layer.

10. The memory of claim 9 wherein select device is an ovonic threshold switch.

11. The memory of claim 9 wherein said heater is made up of at least two distinct layers.

12. The memory of claim 9 wherein said phase change memory element includes a chalcogenide alloy provided between a pair of sidewall spacers.

13. The memory of claim 9 wherein said heater material is spaced from said row line by said select device and said row line is formed of copper.

14. The memory of claim 9 wherein said heater material including etch defined sidewalls.

15. A semiconductor structure comprising:
a select device;
a first heater;
a hard mask formed over said first heater;
a second heater;
a second hard mask formed over said second heater; and
an insulator between said first and second heaters.

16. The structure of claim 15 including an insulator over said hard mask.

17. The structure of claim 16 wherein said hard mask and said insulator have substantially different etch characteristics.

18. The structure of claim 17 wherein said hard mask and said insulator are formed of different materials.

19. The structure of claim 18 wherein said hard mask is selectively etchable relative to said insulator.

20. A system comprising:
a processor;
an input/output device coupled to said processor; and
a phase change memory including an ovonic threshold switch and a heater over said switch, said heater having a height determined by its deposition thickness.

21. The system of claim 20 wherein said memory includes a chalcogenide.

22. The system of claim 20 wherein said memory includes an insulating layer with a heater formed thereon.

23. The system of claim 20 including a heater material having a pair of distinct layers.
